(19) United States
(12) Patent Application Publication
(10) Pub. No.: US 2025/0138159 A1
(43) Pub. Date: May 1, 2025

(54) High-Resolution Solid-State LIDAR Transmitter

(71) Applicant: Opsys Tech Ltd., Holon (IL)

(72) Inventor: Larry Fabiny, Boulder, CO (US)

(73) Assignee: Opsys Tech Ltd., Holon (IL)

(21) Appl. No.: 19/008,252

(22) Filed: Jan. 2, 2025

Related U.S. Application Data
(62) Division of application No. 16/941,896, filed on Jul. 29, 2020, now Pat. No. 12,222,445.
(60) Provisional application No. 62/881,354, filed on Jul. 31, 2019.

(51) Int. Cl. G01S 7/481; G01S 7/48; G01S 17/931

(52) U.S. Cl. CPC G01S 7/4815; G01S 7/4808; G01S 7/4817; G01S 17/931

(57) ABSTRACT

A solid-state LIDAR transmitter includes a laser array comprising first and second laser pixels that each generate first and second sub-aperture beams. A first microlens focuses first and second sub-aperture beams generated by the first laser pixel and focuses first and second sub-aperture beams generated by the second laser pixel. A second microlens directs the first and second sub-aperture beams generated by the first pixel such that they overlap at a plane. A lens projects the first sub-aperture beam generated by the first laser pixel and the first sub-aperture beam generated by the second laser pixel with a different angle in the far field in order to achieve a desired spatial resolution of the LIDAR system.

### CROSS REFERENCE TO RELATED APPLICATION

The present application is a non-provisional application of U.S. Provisional Patent Application No. 62/881,354 filed on Jul. 31, 2019, entitled “High-Resolution Solid-State LIDAR Transmitter”. The entire contents of U.S. Provisional Patent Application No. 62/881,354 are herein incorporated by reference.

The section headings used herein are for organizational purposes only and should not to be construed as limiting the subject matter described in the present application in any way.

### INTRODUCTION

Autonomous, self-driving, and semi-autonomous automobiles use a combination of different sensors and technologies, such as radar, image-recognition cameras, and sonar for detection and location of surrounding objects. These sensors enable a host of improvements in driver safety including collision warning, automatic-emergency braking, lane-departure warning, lane-keeping assistance, adaptive cruise control, and piloted driving. Among these sensor technologies, light detection and ranging (LIDAR) systems take a critical role, enabling real-time, high-resolution 3D mapping of the surrounding environment.

The majority of commercially available LIDAR systems used for autonomous vehicles today utilize a small number of lasers, combined with some method of mechanically scanning the environment. It is highly desired that future autonomous automobiles utilize solid-state semiconductor-based LIDAR systems that support fast scanning rates and ease of integration with high reliability and wide environmental operating ranges.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings, described below, are for illustration purposes only. The drawings are not necessarily to scale, emphasis instead generally being placed upon illustrating principles of the teaching. The drawings are not intended to limit the scope of the Applicant's teaching in any way.

FIG. 1 is a schematic diagram illustrating the operation of an embodiment of a high-resolution LIDAR system of the present teaching implemented in a vehicle.

FIG. 2A illustrates a two-dimensional vertical cavity surface emitting laser (VCSEL) array that can be used in a high-resolution LIDAR system of the present teaching.

FIG. 2B illustrates an array of sub-apertures of the two-dimensional VCSEL array of FIG. 2A.

FIG. 3A illustrates a transmit optical system for projecting optical beams from a laser array that uses two conventional bulk lenses.

FIG. 3B illustrates an expanded view of a portion of the transmit optical system shown in FIG. 3A.

FIG. 3C illustrates a far field pattern generated by the transmit optical system for projecting optical beams from the laser array of FIG. 3A.

FIG. 4A illustrates a transmit optical system for projecting optical beams from a laser array that uses one microlens array and one bulk lens.

FIG. 4B illustrates an expanded view of a portion of the transmit optical system shown in FIG. 4A.

FIG. 4C illustrates a far field pattern generated by the transmit optical system for projecting optical beams from the laser array of FIG. 4A.

FIG. 5A illustrates an embodiment of a transmit optical system for projecting optical beams from a laser array that uses two microlens arrays and a bulk lens of the present teaching.

FIG. 5B illustrates an expanded view of a portion of the transmit optical system shown in FIG. 5A.

FIG. 5C illustrates an embodiment of a far field pattern generated by the transmit optical system for projecting optical beams from the laser array shown in FIG. 5A.

FIG. 6 illustrates a cross-sectional view of an embodiment of a dual-sided microlens array aligned to a VCSEL array of the present teaching.

FIG. 7A illustrates a perspective view showing one side of an embodiment of a dual-sided microlens array of the present teaching.

FIG. 7B illustrates a perspective view showing the other side of the embodiment of the dual-sided microlens array of FIG. 7A.

FIG. 8 illustrates an embodiment of a high-resolution LIDAR transmit system comprising multiple transmit optical systems of the present teaching.

FIG. 9A illustrates a far field pattern for a single LIDAR transmitter using a system for projecting optical beams from a laser array that uses two conventional bulk lenses.

FIG. 9B illustrates a far field pattern for multiple interleaved LIDAR transmitters using a system for projecting optical beams from a laser array that uses one microlens array and one conventional bulk lens.

FIG. 9C illustrates a far field pattern for multiple interleaved LIDAR transmitters using an embodiment of a transmit optical system that projects optical beams from a laser array that uses two microlens arrays and one conventional bulk lens of the present teaching.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

The present teaching relates to Light Detection and Ranging (LIDAR), which is a remote sensing method that uses laser light to measure distances (ranges) to objects. LIDAR systems measure distances to various objects or targets that reflect and/or scatter light. Autonomous vehicles make use of LIDAR systems to generate a highly accurate three-dimensional (3D) map of the surrounding environment with fine resolution. The systems and methods described herein are directed towards providing a solid-state, pulsed time-of-flight (TOF) LIDAR system with high levels of reliability, while also maintaining long measurement range and providing relatively low cost. In particular, LIDAR systems according to the present teaching send out a short time duration laser pulse, and use direct detection of the return pulse in the form of a received return signal trace to measure TOF to the object.

In addition, LIDAR systems of the present teaching are capable of using multiple laser pulses to detect objects with various performance metrics. For example, multiple laser pulses can be used to improve SNR. Multiple laser pulses can also be used to provide greater confidence in the detection of a particular object. For example, particular numbers of laser pulses can be selected to give particular levels of SNR and/or particular confidence values associated with detection of an object. This selection of a number of laser pulses can be combined with selection of an individual or group of laser devices that are associated with a particular pattern of illumination in the FOV.

One feature of the LIDAR systems of present teaching is that the emitters can emit light at different wavelengths. Thus, various emitters in the array can produce light with different wavelengths than other emitters. For example, emitters in a column or in a row may emit one wavelength, and emitters in an alternating column or row may emit a different wavelength. A variety of wavelength patterns of emitted laser light with different wavelengths can be used, for example, to provide desired resolution, operate at long ranges within eye-safe limits of operation, and/or to increase the data rate of the system. See, for example, U.S. Patent Publication No. 20170307736 A1, entitled “Multi-Wavelength LIDAR System” and U.S. Patent Publication No. 20180259623 A1, entitled “Eye-Safe Scanning LIDAR System”, which are both assigned to the present assignee. U.S. Patent Publication Nos. 20170307736 A1 and 20180259623 A1 are incorporated herein by reference.

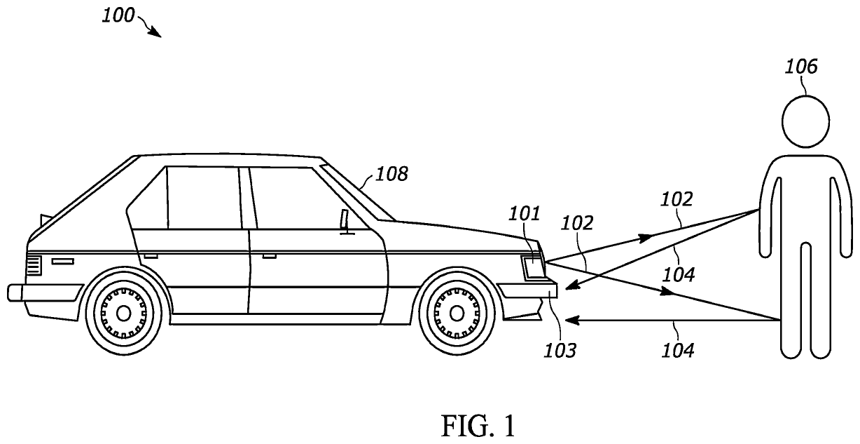

FIG. 1 is a schematic diagram illustrating the operation of a LIDAR system 100 of the present teaching implemented in a vehicle. The LIDAR system 100 includes a transmit optical system, which is described in more detail herein, that projects light beams 102 generated by a laser array in the transmit optical system toward a target scene. The LIDAR system also includes a receiver 103 that receives the light 104 that reflects from an object, shown as a person 106, in that target scene. LIDAR systems typically also include a controller that computes the distance information about the object, person 106, from the reflected light.

In some embodiments, there is also an element that can scan or provide a particular pattern of the light that may be a static pattern or a dynamic pattern across a desired range and field-of-view (FOV). A portion of the reflected light from the object, person 106, is received by the receiver 103. In some embodiments, the receiver comprises receive optics and a detector element that may be an array of detectors. The receiver and controller are used to convert the received signal light into measurements that represent a pointwise 3D map of the surrounding environment that falls within the LIDAR system range and FOV.

Some embodiments of LIDAR systems according to the present teaching use a laser transmitter that includes a laser array. In some embodiments, the laser array comprises VCSEL laser emitters, which may include top-emitting VCSELs, bottom-emitting VCSELs, and/or various types of high-power VCSELs. The VCSEL arrays may be monolithic. The laser emitters may all share a common substrate, including semiconductor substrates or ceramic substrates. A single controlled laser emitter can include multiple sub-apertures that each emit an optical beam when the laser emitter is energized.

In some embodiments, the energizing of individual lasers and/or groups of lasers in embodiments that use one or more transmitter arrays can be individually controlled. Each individual emitter in the transmitter array can be fired independently, with the optical beam emitted by each laser emitter corresponding to a three-dimensional projection angle subtending only a portion of the total system field-of-view. One example of such a LIDAR system is described in U.S. Patent Publication No. 2017/0307736 A1, which is assigned to the present assignee. In addition, the number of pulses fired by an individual laser, or group of lasers can be controlled based on a desired performance objective of the LIDAR system. The duration and timing of this sequence can also be controlled. See, for example, U.S. Provisional Patent Application No. 62/714,463, entitled “Distributed Modular Solid-State LIDAR System”, which is assigned to the present assignee and incorporated herein by reference. See also, U.S. Provisional Patent Application No. 62/859,349, entitled “Eye-Safe Long-Range Solid-State LIDAR System”, and U.S. Provisional Patent Application No. 62/866,119, entitled “Adaptive Multiple-Pulse LIDAR System”, which are also both assigned to the present assignee and incorporated herein by reference.

Another feature of the LIDAR system of the present teaching is that it can provide a compact, reliable transmit optical assembly for a high-resolution LIDAR system. Transmit optical assemblies of the present teaching utilize solid-state laser arrays that, in some embodiments, are fabricated on the same substrate. The substrate can be a semiconductor substrate. Electrical drive circuits are also fabricated on these array substrates that allow each laser in the array to be controlled individually. These arrays can be two-dimensional arrays that use a regular row and column configuration. The electrical control drive scheme can be configured in a so-called matrix configuration, where an individual laser is addressed by appropriate application of an electrical control signal to a particular column and a particular row that contains that individual laser. See, for example, U.S. patent application Ser. No. 16/841,930, entitled “Solid-State LIDAR Transmitter with Laser Control”, which is assigned to the present assignee and is incorporated herein by reference.

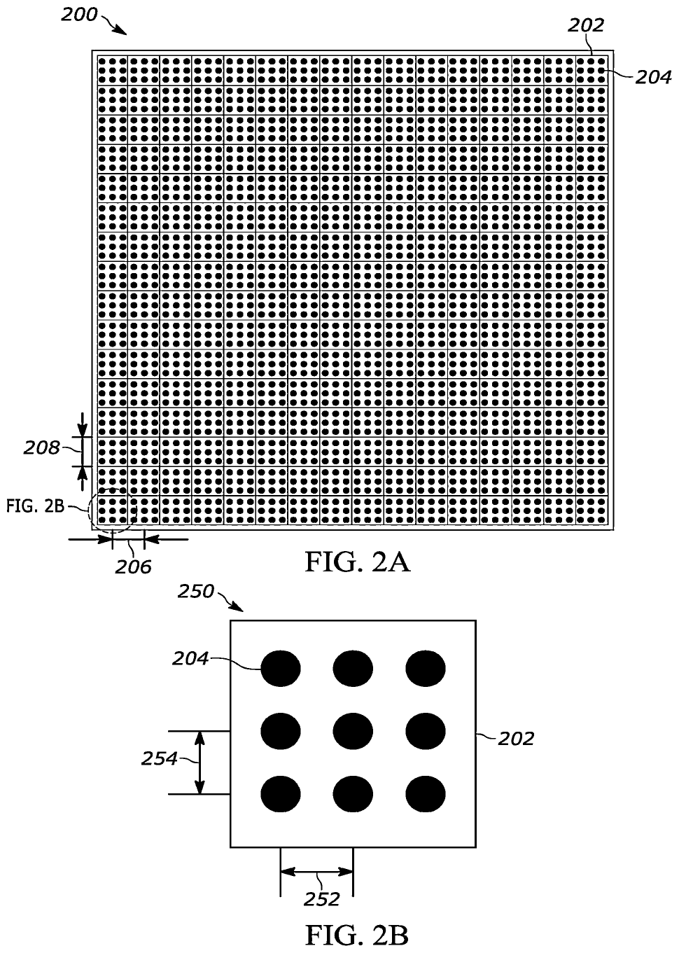

FIG. 2A illustrates a two-dimensional vertical cavity surface emitting laser (VCSEL) array 200 that can be used in a high-resolution LIDAR system of the present teaching. The laser array 200 includes a 16×16 array of individual laser pixels 202, where each pixel 202 incorporates a 3×3 array of sub-apertures 204. In some embodiments, each pixel 202 is addressable individually by applying the correct electrical control signal to a row and column corresponding to that pixel 202 in the array. Thus, individual pixels 202 are energized independently, and all sub-apertures 204 within one pixel 202 are energized together with the energization of the pixel 202. Thus, nine optical beams are provided for each pixel that is energized.

The array 200 has a pixel pitch 206 in the x-direction and a pixel pitch 208 in the y-direction. In some embodiments, the x-directed pixel pitch 206 is equal to the y-directed pixel pitch 208. For example, in one particular embodiment, the x-directed pixel pitch is 250 μm and the y-directed pixel pitch is 250 μm. The number of elements in the array 200 varies in various embodiments. The array pixel pitch may take on various values in various embodiments. It should be understood that while many examples provided herein describe arrays of particular sizes, the present teaching is not limited to any particular array size. One feature of the present teaching is that the solid state, microfabricated components can scale to large sizes simply, cost effectively and have high reliability.

FIG. 2B illustrates an array 250 of sub-apertures of the two-dimensional VCSEL array 200 of FIG. 2A. A single pixel 202 is shown. Each pixel 202 has nine sub-apertures 204 configured in a 3×3 array. Each pixel 202 has an x-directed sub-aperture pitch 252 and a y-directed sub-aperture pitch 254. The sub-apertures 204 associated with an individual pixel 202 are all energized at the same time in response to an appropriate electrical control signal. As such, all sub-apertures 204 within an individual pixel 202 illuminate at the same time. Thus, multiple optical beams are generated, one from each aperture in the pixel, upon application of the electrical control signal to a pixel 202. In some embodiments, the x-directed sub-aperture pitch 252 is equal to the y-directed sub-aperture pitch 254. For example, in one specific embodiment, the x-directed sub-aperture pitch is 76 μm and the y-directed sub-aperture pitch is 76 μm. The number of apertures in the sub-array of an individual pixel varies in various embodiments. The array sub-aperture pitch may take on various values in various embodiments.

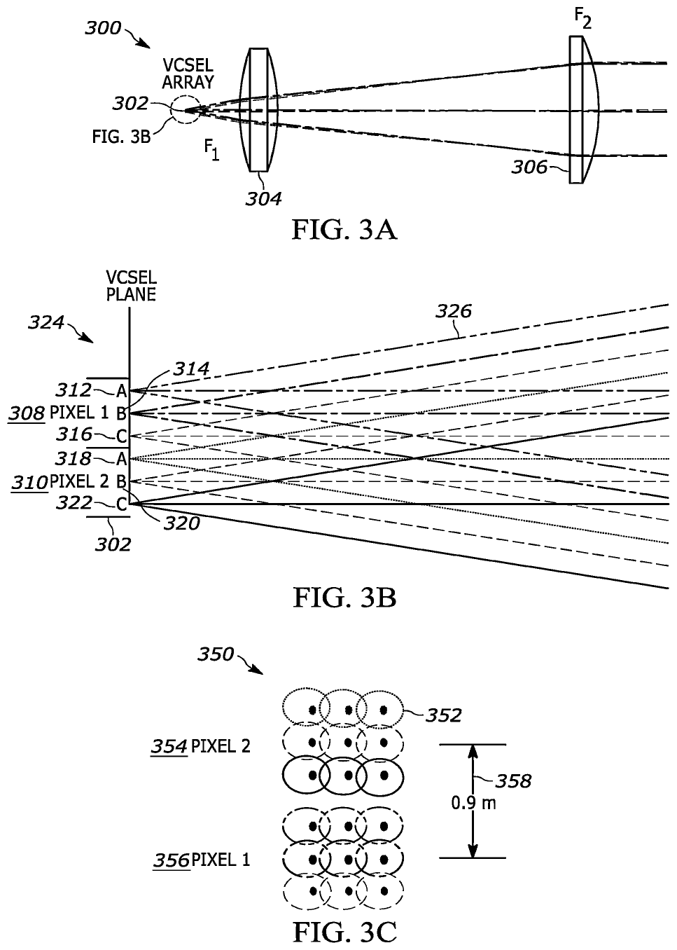

FIG. 3A illustrates a transmit optical system 300 for projecting optical beams from a laser array 302 that uses two conventional bulk lenses 304, 306. The laser array 302 may be the same or similar to the laser array 200 described in connection with FIGS. 2A-B, for example.

FIG. 3B is an expanded view of a portion of the transmit optical system 300 shown in FIG. 3A. The laser array 302 is shown in one dimension and includes individual pixels 308, 310. Only two pixels are shown, pixel 1 308 and pixel 2 310. The pixels 308, 310 each have sub-aperture arrays. Also, show in one dimension are sub-apertures A 312, B 314 and C 316 of pixel 1 308 and sub-apertures A 318, B 320 and C 322 of pixel 2 310. Optical beams 326 from each sub-aperture 312, 314, 316, 318, 320, 322 are emitted and diverge as shown in the expanded view 324. The divergence angle for each beam is related to the size of the respective sub-aperture.

Referring to both FIGS. 3A and 3B, the individual diverging optical beams 326 pass through a bulk lens 304 with a focal length, F1, which is positioned at a distance from the array 302 and a second bulk lens 306 with a focal length, F2, which is positioned at a distance from the first bulk lens 304. The positions of the lenses 304, 306 and their focal lengths F1, F2 determine a projected far field pattern of the transmit optical system 300. For this optical system, the two bulk lenses 304, 306 are configured to nominally generate an image of the laser array 302 in the far field. Thus, the laser array pattern is recreated in the far field, magnified to a desired size based on the lens configuration, and the sub-apertures from individual pixels are separated in space. The angular field-of-view (FOV) of each pixel is approximately the same as the angle spacing between pixels.

FIG. 3C illustrates a far field pattern 350 generated by the transmit optical system 300 for projecting optical beams from the laser array of FIG. 3A. The far field spots are shown for two vertically adjacent pixels, where each pixel comprises a 3×3 array of sub-apertures at 50-meter range. This example far field pattern 350 is produced at a 50-meter distance from the optical system 300. The pattern 350 includes nine individual spots 352 for each pixel region 354, 356. The individual pixel regions 354, 356 are spaced a distance of 0.9 meters at the 50-meter range. The pixel-spot-size-to-pixel-pitch ratio is ˜0.9.

FIGS. 3A-C illustrate only a portion of, for example, a 16×16 array of lasers that each have nine sub-apertures. For a full 16×16 array, the pattern will appear as (16×3)×(16×3) spots, or 48×48 spots.

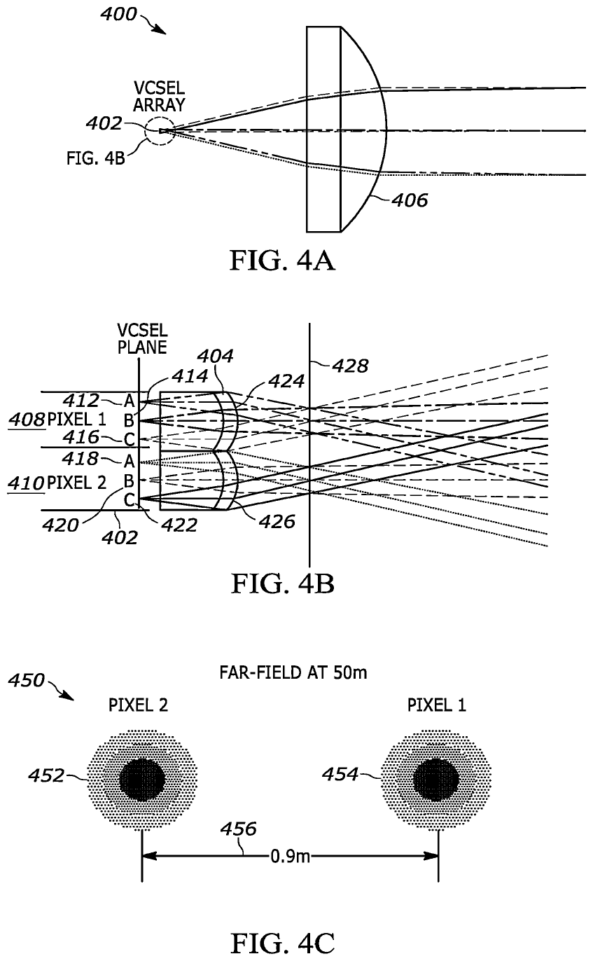

It is possible to reduce the spot sizes from the emitters in the far field by using a small lens placed close to the laser emitter to nominally collimate and/or focus each of the optical beams. FIG. 4A illustrates a transmit optical system 400 for projecting optical beams from a laser array 402 that uses one microlens array 404 and one bulk lens 406.

FIG. 4B is an expanded view of a portion of the transmit optical system 400 shown in FIG. 4A. Referring to both FIGS. 4A and 4B, in this transmit optical system 400, the microlens array 404 has a pitch equal to the pitch of the pixels, pixel 1 408 and pixel 2 410, in the array 402. The microlens array 404 collimates each sub-aperture, sub-apertures A 412, B 414, and C 416, of pixel 1 408, and sub-apertures A 418, B 420, and C 422 of pixel 2 410. The microlens array 404 comprises multiple lenslets 424, 426 that are spaced at a pitch that is the same as the pixel pitch of the laser array 402.

Each lenslet 424, 426 collimates a beam emitted from a respective pixel 408, 410. The collimated beams from each sub-aperture 412, 414, 416, 418, 420, 422 overlap at a plane Z1 428 that is located one focal distance away from the lenslets 424, 426 in the microlens array 404. The bulk lens 406 has a focal length, F2, and is positioned a distance of F2 from the plane Z1 428. The bulk lens 406 projects the optical beams from each pixel along nominally parallel paths to the far field.

FIG. 4C illustrates a far field pattern 450 generated by the transmit optical system 400 for projecting optical beams from the laser array 402 of FIG. 4A. The far field spots are shown for two vertically adjacent pixels, where each pixel comprises a 3×3 array of sub-apertures at 50-meter range. The far field pattern 450 results in two large spots 452, 454 that are separated by a 0.9-meter distance 456 at a range of 50 meters. In large spot 454, the optical beams from all nine sub-apertures from a single pixel 408 overlap. The pixel-spot-size-to-pixel-pitch ratio is ˜0.5.

Note that FIG. 4A only illustrates three sub-apertures 412, 414, 416 for pixel 1 408 because it is a side view, but the far-field pattern 450 is illustrated in two dimensions and so shows a spot provided by all nine sub-apertures of pixel 1 408. Likewise, for pixel 2 410 and associated spot 452. The pixel-spot-size-to-pixel-pitch ratio for this transmit optical system is ˜0.5.

A LIDAR system that uses the transmit optical system 400 illustrated in FIGS. 4A-C has improved the resolution because it has reduced the spot size as compared to systems that do not use microlenses for collimation. However, a feature of the present teaching is the realization that the use of two patterned back-to-back microlens arrays can provide further improvement to the LIDAR system resolution.

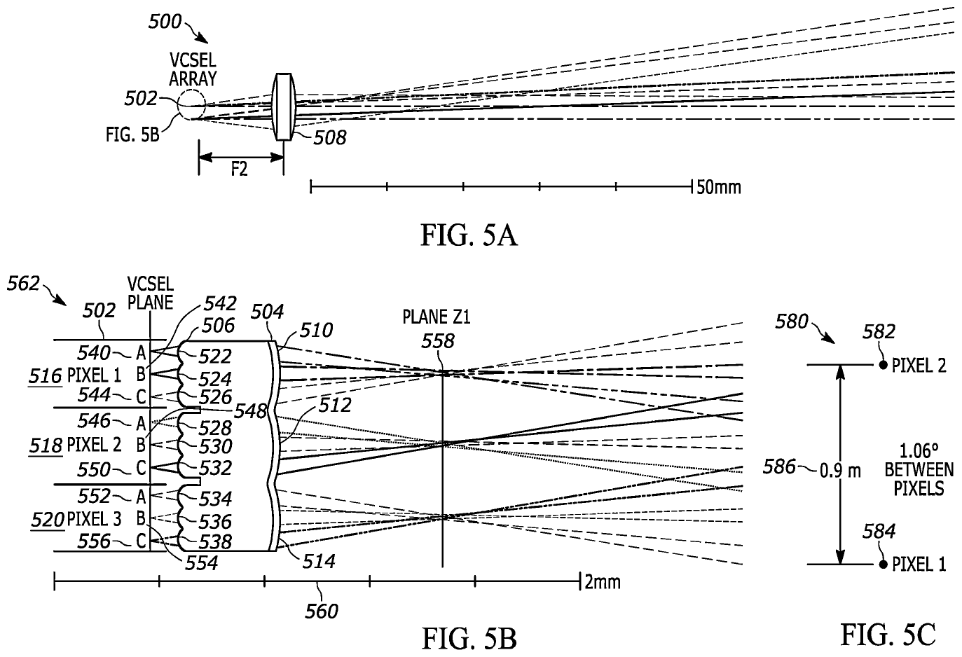

FIG. 5A illustrates an embodiment of a transmit optical system 500 for projecting optical beams from a laser array 502 that uses two microlens arrays 504, 506 and a bulk lens 508 of the present teaching.

FIG. 5B is an expanded view of a portion of the transmit optical system 500 shown in FIG. 5A. Referring to both FIG. 5A and 5B, one microlens array 504 has lenslets 510, 512, 514 spaced at a pitch equal to the pitch of the pixels, pixel 1 516 and pixel 2 518, and pixel 3 520 in the laser array 502. Another microlens array 506 has lenslets 522, 524, 526, 528, 530, 532, 534, 536, 538 spaced at a pitch equal to the pitch of sub-apertures 540, 542, 544, 546, 548, 550, 552, 554, 556 of the laser array 502. Thus, microlens 506 comprises one lenslet per sub-aperture, and microlens 504 comprises one lenslet per pixel. Microlens array 506 acts on each of the optical beams generated in each sub-aperture 540, 542, 544, 546, 548, 550, 552, 554, 556 such that each sub-aperture beam is focused without changing the propagation axis of those optical beams. Microlens 504 redirects the optical beams from each sub-aperture 540, 542, 544, 546, 548, 550, 552, 554, 556 so that they overlap at the back focal plane Z1 558 of the lenslets 510, 512, 514. Thus, the optical beams from each sub-aperture 540, 542, 544, 546, 548, 550, 552, 554, 556 are focused at the overlap plane at back focal plane Z1 558 by the combined action of microlens array 506 and microlens array 504. The bulk lens 508 is positioned a distance equal to a focal length of the lens 508, F2, from the plane Z1 558. The combination of the microlens arrays 504, 506 creates an intermediate real image of an array of spots with the same pitch as the laser array 502 at a plane Z1 558. The bulk lens 508 projects each of the spots from Z1 558 to a different angle in the far field. The particular projected angle from the bulk lens 508 is a function of the perpendicular distance of the corresponding array spot from the principal optical axis of the system.

One feature of the present teaching is the use of two back-to-back micro lens arrays 504, 506 that serve to focus optical beams from each sub-aperture and direct those beams to overlap at a back focal plane of the second lens 504. As is clear from the scale 560 in the expanded view 562, these two microlens array 504, 506 designs are very compact, and nominally focused overlapped beams occur at a distance of less than 2 mm from the laser array 502. In some embodiments, the microlens arrays 504, 506 are fabricated on a front and back surface of the same substrate. This advantageously provides a very compact system that is easy to assemble. In some embodiments, the microlens arrays 504, 506 are fabricated on separate substrates. In some embodiments, one or both of the microlens arrays 504, 506 may be refractive optical elements. In some embodiments, one or both of the microlens arrays 504, 506 may be diffractive optical elements. In some embodiments, one or both of the microlens arrays 504, 506 may be holographic optical elements.

FIG. 5C illustrates an embodiment of a far field pattern 580 generated by the transmit optical system 500 for projecting optical beams from a laser array 502 of FIG. 5A. The far field spots are shown for two vertically adjacent pixels, where each pixel comprises a 3×3 array of sub-apertures at 50-meter range. Note that the system diagram of FIG. 5A shows a side view of the 2-dimensional arrays, but FIG. 5C illustrates a two-dimensional pattern in a plane perpendicular to the principle axis. Only portions of the system are illustrated for clarity. The far field pattern 580 results in two small spots 582, 584 that are separated by a 0.9-meter distance 586 at a range of 50 meters. Spots 582, 584 are only shown for two pixels 516, 518. There is 1.06 degrees between pixels, resulting in 0.9-meter separation distance 586 at the 50-meter range. The pixel-spot-size-to-pixel-pitch ratio is ˜0.1. The ultimate resolution is determined by the spot size from one pixel relative to the spot separation between spots from adjacent pixels. Thus, the transmit optical system of the present teaching advantageously provides a much smaller pixel spot size-to-pixel-pitch ratio in the far field. This improves system resolution and also allows for effective and scalable interleaving of multiple transmit optical systems that provides many benefits for data collection, including the support of high data collection rates and flexibility in illumination patterns and timing sequences.

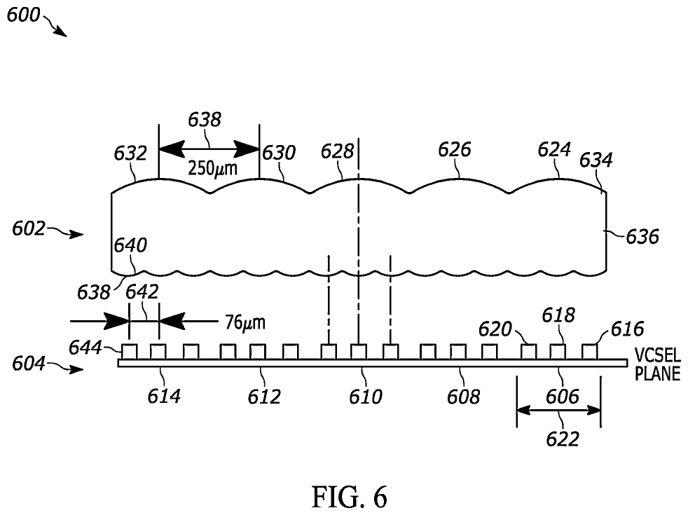

FIG. 6 illustrates a cross-sectional view 600 of an embodiment of a dual-sided microlens array 602 aligned to a VCSEL array 604 of the present teaching. The VCSEL includes five pixels 606, 608, 610, 612, 614. Each pixel 606, 608, 610, 612, 614 comprises nine sub-apertures. For example, three sub-apertures 616, 618, 620 are visible in the cross-sectional view 600 for pixel. The pixels are arranged in an array with pitch 622. Five-pixel lenslets 624, 626, 628, 630, 632 are formed on a first surface 634 of a substrate 636. The pixel lenslets 624, 626, 628, 630, 632 are arranged in an array with pitch 638 and match the array of pixels 606, 608, 610, 612, 614 in the VCSEL array 604. Formed on a second surface 638 of substrate 636 are sub-aperture lenslets 640 that are set on pitch 642 which matches the pitch of the sub-apertures of the VCSEL array 604. This microlens array 602 configuration can be referred to as a dual-sided microlens. In one particular embodiment, the pixel pitch is 250 μm and the sub-aperture pitch is 76 μm. In some embodiments, the laser and microlens arrays 602, 604 are one-dimensional. Also, in some embodiments, the microlens arrays 602, 604 are two-dimensional. In various embodiments, the microlens arrays 602, 604 contain different numbers of pixels, sub-apertures, pixel lenslets and/or sub-aperture lenslets. In some embodiments, the pixel pitch 622 is not an integer multiple of the sub-aperture pitch 642. In some embodiments, the sub-aperture pitch 642 does not extend across the boundaries of a pixel.

In some embodiments, the sub-aperture lenslet 640 side of the microlens array 602 is positioned closest to the VCSEL array 604. The pixel lenslet surface 634 is positioned furthest from the VCSEL array 602, with each lenslet 624, 626, 628, 630, 632 centered directly above a pixel. This positioning is specifically illustrated in FIG. 6, for example, for pixel lenslet 628 over pixel 610. The sub-aperture lenslets are centered directly above a sub-aperture. This is illustrated in FIG. 6, for example, for sub-aperture lenslet 640 above sub-aperture 644.

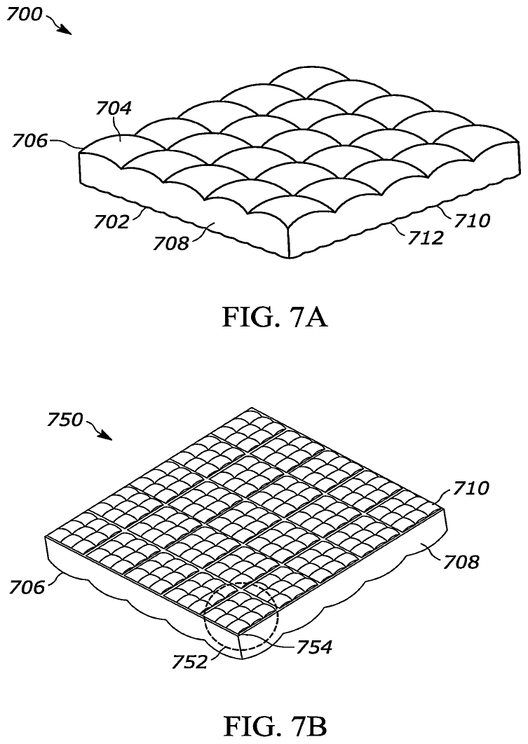

FIG. 7A illustrates a perspective view 700 showing one side of an embodiment of a dual-sided microlens array 702 of the present teaching. Pixel lenslets 704 are formed on one surface 706 of the substrate 708. The lenslets 704 have a pitch that matches the pitch of, for example, a VCSEL array such that there is one lens per pixel in an embodiment of a transmit optical system of the present teaching. A 5×5 array of lenslets 704 is illustrated in the perspective view 700. The sub-aperture lenslets 712 are visible on the other surface 710 of the substrate 708.

FIG. 7B illustrates a perspective view 750 showing the other side of the dual-sided microlens array of FIG. 7A. A circle 752 highlights a 9×9 array of sub-aperture lenslets 754 that are formed on the other surface 710 of the substrate. The sub-aperture lenslet 754 pitch is matched to the pitch of a matching array of lasers, for example, the sub-apertures of a VCSEL array. There are nine sub-aperture lenslets per pixel.

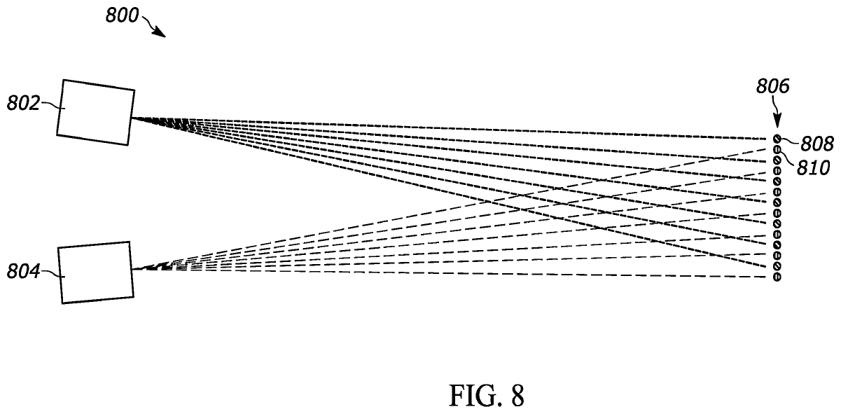

FIG. 8 illustrates an embodiment of a high-resolution LIDAR transmit system 800 comprising multiple transmit optical systems 802, 804 of the present teaching. One feature of the present teaching is that the two microlens array configuration described herein makes it possible to use separate transmit optical systems that are aligned so that the total FOV generated by one transmit optical system 802 is offset by less than one pixel FOV from the total FOV generated by a second transmit optical system 804. This type of configuration can be referred to as an interleaved configuration. By interleaving the light from the two transmit optical systems 802, 804, the spatial resolution of the LIDAR system comprising the interleaved transmit system 800 is greatly improved compared with LIDAR systems that use only one transmit optical system.

The interleaving will have uniform spacing between spots generated by each of two different transmit optical systems (sometimes called perfect interleaving) at one target distance only. However, because the separation between the transmit optical systems 802, 804 can be small, in some embodiments separations are on the order of 10's of millimeters, and the target distances in some embodiments are on the order of 10's of meters, even imperfect interleaving is acceptable and improves resolution. Thus, improved resolution by interleaving the transmit optical systems 802, 804 is possible over a range of target distances using transmit optical systems of the present teaching. FIG. 8 shows the array of interleaved spots 806 at one target distance, illustrating the interleaving of a first array of spots 808 from transmit optical system 802 and a second array of spots 810 from transmit optical system 804.

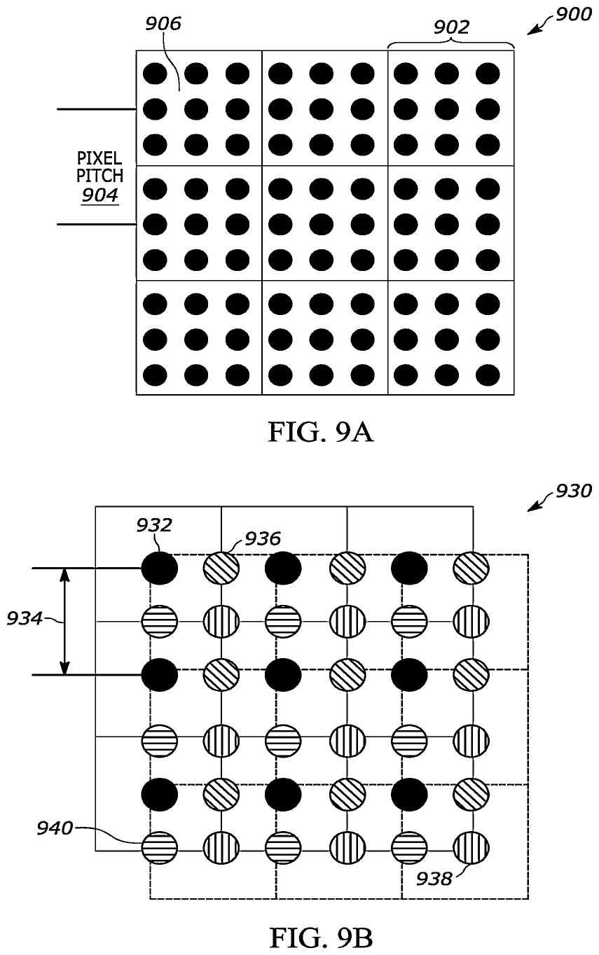

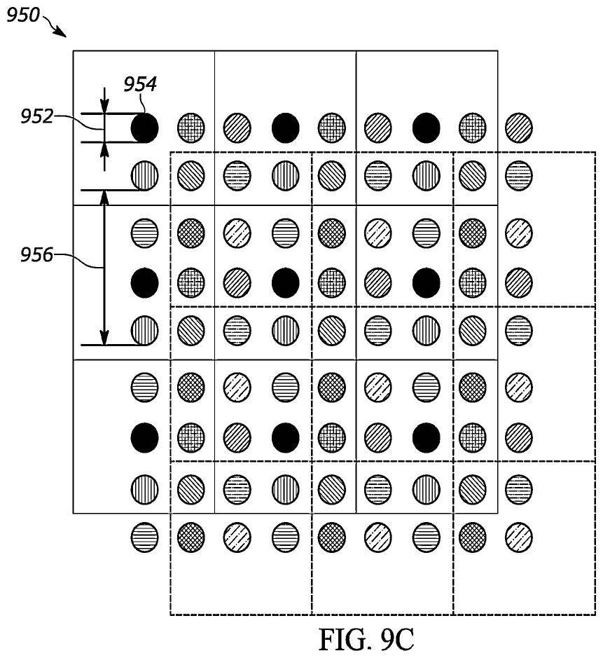

FIG. 9A illustrates a far field pattern 900 for a single solid-state LIDAR transmitter using a system for projecting optical beams from a laser array that uses two conventional bulk lenses, as illustrated in FIG. 3A. The pixel spot size 902 and pixel pitch 904 are nominally the same. The pixel spot size 902 is a full pixel. All the sub-aperture spots are illuminated by a control signal applied to energize that pixel and associated sub-apertures. As such, it is not possible to interleave pixel spots 906 from two different transmit optical systems that use only two bulk lenses and no microlenses. The pixel-spot-size-to-pixel-pitch in the far field is close to one for this system. As a result, there is no room to interleave the spots and provide an improved resolution by using two optical transmit systems.

FIG. 9B illustrates a far field pattern 930 for multiple interleaved solid-state LIDAR transmitters using a system for projecting optical beams from a laser array that uses one microlens array and one conventional bulk lens, as illustrated, for example, in FIG. 4A. In this configuration, a spot size from a single energized pixel is shown as a shaded spot 932, which is smaller than the pixel FOV pitch 934. The ratio of pixel-spot-size-to-pixel-pitch in the far field is close to 0.5 for this system. Thus, in this case it is possible to interleave, e.g. four transmit optical systems. This produces four different pixel spots 932, 936, 938, 940 that are associated with the four different transmit optical systems. The interleaving of spots from four different transmit optical systems increases the spatial resolution by a factor of two in each dimension.

FIG. 9C illustrates a far field pattern 950 for multiple interleaved solid state LIDAR transmitters using an embodiment of a transmit optical system that projects optical beams from a laser array that uses two microlens arrays and one conventional bulk lens of the present teaching. This embodiment of the transmit optical system could be, for example, the embodiment shown in FIG. 5A. In this configuration, a pixel spot size 952 of a single pixel spot 954 is very small as compared to the pixel FOV pitch 956. In some embodiments, the ratio of pixel-spot-size-to-pixel-pitch in the far field is less than 0.1. It is possible to interleave spots 954 from at least nine transmit optical systems to increase spatial resolution. Different shades are used to illustrate pixel spots from different transmit optical systems.

The examples described in connection with FIGS. 9A-C illustrate far field patterns 900, 930, 950 generated by a VCSEL array with a 3×3 grid of pixels where each pixel includes a 3×3 grid of sub-apertures. Scaling to different array sizes and/or shapes for both pixels and/or sub-aperture sizes and/or shapes is a straightforward extension.

Thus, one feature of the transmit optical systems that utilize the combination of sub-aperture microlenses to focus optical beams from VCSEL pixel sub-aperture emitters, pixel microlenses to redirect the sub-aperture optical beams to their focus at an overlap point, and a bulk lens to project the sub-aperture beams in each pixel to a different angle in a far field is that it improves spatial resolution sufficiently to allow interleaving of transmit optical systems. This improvement is in part because a smaller far field pixel-spot-size-to-pixel-pitch ratio is achieved. The different projected angles in the far field are based on the position of a particular pixel optical beam with respect to the central, or principle axis of the bulk lens. Thus, by using bulk lenses with different focal lengths and positions, a variety of far-field projection angles can be achieved.

### Equivalents

While the Applicant's teaching is described in conjunction with various embodiments, it is not intended that the Applicant's teaching be limited to such embodiments. On the contrary, the Applicant's teaching encompasses various alternatives, modifications, and equivalents, as will be appreciated by those of skill in the art, which may be made therein without departing from the spirit and scope of the teaching.

1. A solid-state Light Detection and Ranging (LIDAR) transmitter comprising:
a) a laser array comprising:
i) a first laser pixel comprising a first and second sub-aperture that are positioned with a first sub-aperture spacing, each of the first and second sub-apertures generating a sub-aperture beam when energized; and
ii) a second laser pixel comprising a first and second sub-aperture that are positioned with a second sub-aperture spacing, each of the first and second sub-apertures generating a sub-aperture beam when energized, the first and second laser pixel being positioned relative to each other with a pixel spacing;
b) a first microlens comprising a first sub-aperture lenslet and a second sub-aperture lenslet that are positioned with the first sub-aperture spacing and comprising a third sub-aperture lenslet and a fourth sub-aperture lenslet that are positioned with the second sub-aperture spacing, the first microlens being positioned such that the first sub-aperture lenslet is in an optical path of the first sub-aperture beam generated by the first sub-aperture of the first laser pixel and being positioned such that the third sub-aperture lenslet is in an optical path of the first sub-aperture beam generated by first sub-aperture of the second laser pixel, the first microlens being configured to focus the first and second sub-aperture beams generated by the first and second sub-aperture of the first laser pixel and to focus the first and second sub-aperture beams generated by the first and second sub-aperture of the second laser pixel;
c) a second microlens comprising a first pixel lenslet and second pixel lenslet that are positioned relative to each other with the pixel spacing, wherein the first pixel lenslet is positioned in an optical path of both the first and second sub-aperture beams generated by the first and second sub-aperture of the first laser pixel, the second microlens being configured to direct the first and second sub-aperture beams generated by the first and second sub-aperture of the first laser pixel such that they overlap at a plane; and
d) a lens positioned in the path of the first and second sub-aperture beams generated by the first and second sub-aperture of the first laser pixel, the lens being configured to project the first sub-aperture beam generated by the first sub-aperture of the first laser pixel and the first sub-aperture beam generated by the first sub-aperture of the second laser pixel with a different angle in the far field in order to achieve a desired spatial resolution of the LIDAR system.

2. The solid-state LIDAR transmitter of claim 1 wherein the laser array comprises a one-dimensional laser array.

3. The solid-state LIDAR transmitter of claim 1 wherein the laser array comprises a two-dimensional laser array.

4. The solid-state LIDAR transmitter of claim 1 wherein the laser array comprises a Vertical Cavity Surface Emitting Laser Array (VCSEL).

5. The solid-state LIDAR transmitter of claim 1 wherein at least one of the first and the second microlens are formed on the same side of a substrate.

6. The solid-state LIDAR transmitter of claim 1 wherein the first and second microlens are configured so that a ratio of a far-field-pixel-spot-size-to-a-pixel-pitch ratio is less than 1.

7. The solid-state LIDAR transmitter of claim 1 wherein the first and second microlens are configured so that a ratio of a far-field-pixel-spot-size-to-a-pixel-pitch ratio is less than 0.5.

8. The solid-state LIDAR transmitter of claim 1 wherein the first and second microlens are configured so that a ratio of a far-field-pixel-spot-size-to-a-pixel-pitch ratio is less than 0.2.

9. The solid-state LIDAR transmitter of claim 1 wherein the second microlens array is configured so that the plane is located at a distance from the second microlens equal to a focal length of the first pixel lenslet.

10. The solid-state LIDAR transmitter of claim 1 wherein the second microlens array is configured so that the plane is located at a distance that is less than 2 mm from the laser array.

11. The solid-state LIDAR transmitter of claim 1 wherein the lens is positioned at a distance from the plane that is equal to a focal length of the lens.

12. The solid-state LIDAR transmitter of claim 1 wherein at least one of the first microlens, second microlens, and the lens is configured to project the first and second sub-aperture beams of the first pixel so that they overlap in the far field such that the LIDAR system achieves a resolution of less than 0.2 degrees.

13. The solid-state LIDAR transmitter of claim 1 wherein at least one of the first and second microlens array comprises a refractive optical element.

14. The solid-state LIDAR transmitter of claim 1 wherein at least one of the first and second microlens array comprises a diffractive optical element.

15. The solid-state LIDAR transmitter of claim 1 wherein at least one of the first and second microlens array comprises a holographic optical element.

16. The solid-state LIDAR transmitter of claim 1 wherein the first microlens is configured to focus the first and second sub-aperture beam of the first pixel and to focus the first and second sub-aperture beam of the second pixel at the plane.

17-29. (canceled)
